(19) United States
(12) Patent Application Publication
(10) Pub. No.: US 2024/0012331 A1
(43) Pub. Date: Jan. 11, 2024

(54) METHOD OF MANUFACTURING PATTERNED BASE MEMBER, PROCESSING METHOD, AND METHOD OF MANUFACTURING LASER ELEMENT

(71) Applicant: NICHIA CORPORATION, Anan-shi (JP)

(72) Inventor: Tsutomu YAMADA, Anan-shi (JP)

(21) Appl. No.: 18/348,313

(22) Filed: Jul. 6, 2023

(30) Foreign Application Priority Data
Jul. 7, 2022 (JP) 2022-109497

(51) Int. Cl. G03F 7/40; G03F 7/20

(52) U.S. Cl. CPC G03F 7/40; G03F 7/2037; H01S 5/12

(57) ABSTRACT

A method of manufacturing a patterned base member includes forming a resist layer including a positive resist on a base member, exposing a portion of the resist layer to an electron beam to form an exposed portion and an unexposed portion in the resist layer, developing the resist layer to remove the exposed portion and leave the unexposed portion to provide a patterned resist layer, irradiating an entirety of the patterned resist layer with an electron beam, and etching the base member using the patterned resist layer as an etching mask or using a patterned mask layer, to which a pattern of the patterned resist layer is transferred, as an etching mask.

### CROSS-REFERENCE TO RELATED APPLICATIONS

The present application claims priority under 35 U.S.C. § 119 to Japanese Patent Application No. 2022-109497, filed Jul. 7, 2022, the contents of which are hereby incorporated herein by reference in their entirety.

### BACKGROUND

The present invention relates to a method of manufacturing a patterned base member, a processing method, and a method of manufacturing a laser element.

Patterning of a resist by electron beam irradiation is expected to be applied to, for example, nano-scale micromachining. For example, Japanese Unexamined Patent Application Publication No. 2011-165980 discloses a method of manufacturing a nanoimprint mold using a combination of a positive resist and a negative resist as an etching mask exposed to an electron beam.

### SUMMARY

Japanese Unexamined Patent Application Publication No. 2011-165980 focuses on the disturbance of the pattern when the positive resist is formed, but the shape of the positive resist may be changed at the time of etching after the formation. As the pattern to be obtained becomes finer, the influence of the change in shape becomes larger, and in some cases, an intended pattern cannot be formed on a workpiece depending on the magnitude of the change.

A method of manufacturing a patterned base member of one embodiment of the present disclosure includes forming a resist layer including a positive resist on a base member, exposing a portion of the resist layer to an electron beam to form an exposed portion and an unexposed portion in the resist layer, developing the resist layer to remove the exposed portion and leave the unexposed portion to provide a patterned resist layer, irradiating an entirety of the patterned resist layer with an electron beam, and etching the base member using the patterned resist layer as an etching mask or using a patterned mask layer to which the pattern of the patterned resist layer is transferred, as an etching mask.

A processing method of one embodiment of the present disclosure includes providing the patterned base member manufactured by the above method, transferring the pattern of the patterned base member to a processing resist layer disposed on a workpiece to provide a patterned processing mask layer, and etching the workpiece using the patterned processing mask layer as an etching mask.

A method of manufacturing a laser element of one embodiment of the present disclosure includes forming a semiconductor layered body including a plurality of semiconductor layers and forming a diffraction grating in the semiconductor layered body by the above processing method.

In the method of manufacturing a laser element of one embodiment of the present disclosure, the base member is a nitride semiconductor substrate, and the method includes providing a patterned substrate as the patterned base member manufactured by the above method and layering a plurality of semiconductor layers on the patterned substrate.

A method of manufacturing a patterned base member of one embodiment of the present disclosure can improve the accuracy of the pattern of the resulting patterned base member. A processing method of one embodiment of the present disclosure can improve the processing accuracy. A method of manufacturing a laser element of one embodiment of the present disclosure can improve the accuracy of patterning on a laser element.

### BRIEF DESCRIPTION OF THE DRAWINGS

Amore complete appreciation of embodiments of the invention and many of the attendant advantages thereof will be readily obtained by reference to the following detailed description when considered in connection with the accompanying drawings.

FIG. 1 is a flowchart illustrating a method of manufacturing a patterned base member of a first embodiment.

FIG. 2A is a schematic cross-sectional view illustrating a step of the method of manufacturing a patterned base member of the first embodiment.

FIG. 2B is a schematic top view illustrating a step of the method of manufacturing a patterned base member of the first embodiment.

FIG. 2C is a schematic cross-sectional view taken along the line IIC of FIG. 2B.

FIG. 2D is a schematic cross-sectional view illustrating a step of the method of manufacturing a patterned base member of the first embodiment.

FIG. 2E is a schematic cross-sectional view illustrating a step of the method of manufacturing a patterned base member of the first embodiment.

FIG. 2F is a schematic cross-sectional view illustrating a step of the method of manufacturing a patterned base member of the first embodiment.

FIG. 3 is a flowchart illustrating a manufacturing method of a modification of the first embodiment.

FIG. 4A is a schematic cross-sectional view illustrating a step of the manufacturing method of the modification of the first embodiment.

FIG. 4B is a schematic cross-sectional view illustrating a step of the manufacturing method of the modification of the first embodiment.

FIG. 4C is a schematic cross-sectional view illustrating a step of the manufacturing method of the modification of the first embodiment.

FIG. 5 is a micrograph of a patterned resist layer after an electron beam irradiation step and a step of providing a patterned mask layer taken with a scanning electron microscope (SEM).

FIG. 6 is an SEM micrograph of a patterned resist layer after the step of providing a patterned mask layer without the electron beam irradiation step.

FIG. 7 is a flowchart illustrating a processing method of a second embodiment.

FIG. 8A is a schematic cross-sectional view illustrating a step of the processing method of the second embodiment.

FIG. 8B is a schematic cross-sectional view illustrating a step of the processing method of the second embodiment.

FIG. 8C is a schematic cross-sectional view illustrating a step of the processing method of the second embodiment.

FIG. 8D is a schematic cross-sectional view illustrating a step of the processing method of the second embodiment.

FIG. 8E is a schematic cross-sectional view illustrating a step of the processing method of the second embodiment.

FIG. 9 is a flowchart illustrating a method of manufacturing a laser element of a third embodiment.

FIG. 10A is a schematic cross-sectional view illustrating a step of the method of manufacturing a laser element of the third embodiment.

FIG. 10B is a schematic cross-sectional view illustrating a step of the method of manufacturing a laser element of the third embodiment.

FIG. 10C is a schematic cross-sectional view illustrating a step of the method of manufacturing a laser element of the third embodiment.

FIG. 11 is a flowchart illustrating a method of manufacturing a laser element of a fourth embodiment.

FIG. 12A is a schematic cross-sectional view illustrating a step of the method of manufacturing a laser element of the fourth embodiment.

FIG. 12B is a schematic cross-sectional view illustrating a step of the method of manufacturing a laser element of the fourth embodiment.

### DETAILED DESCRIPTION OF EMBODIMENTS

Certain embodiments of the present invention will be described below with reference to the accompanying drawings as appropriate. The embodiments disclosed below are intended to give a concrete form to the technical idea of the present invention and are not intended to limit the present invention to the embodiments below unless specifically stated otherwise. Sizes or positional relationships of members illustrated in each drawing may be exaggerated in order to clarify the descriptions.

### First Embodiment

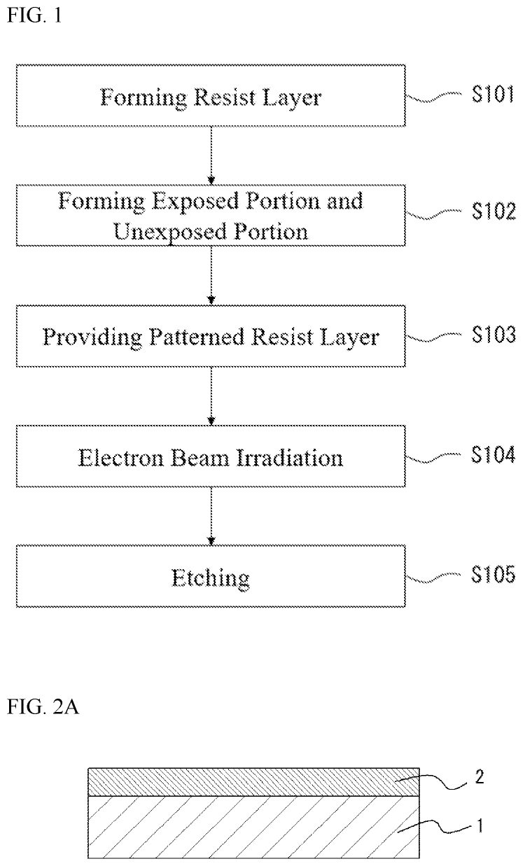

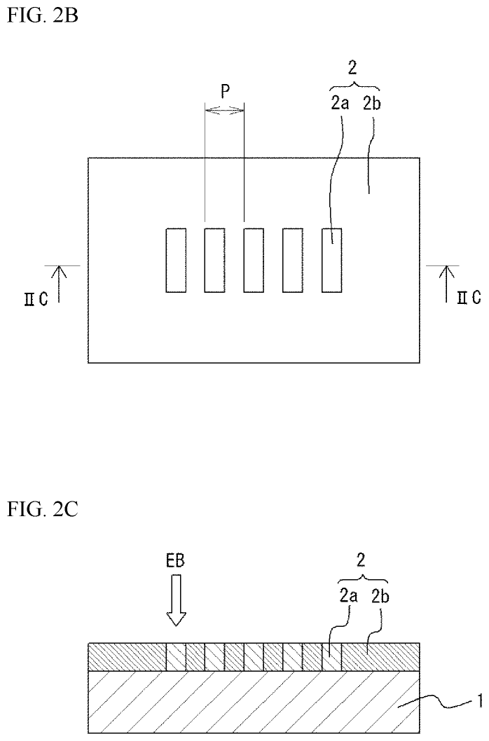

A method of manufacturing a patterned base member according to a first embodiment is described referring to FIG. 1 to FIG. 2F. FIG. 1 is a flowchart illustrating the method of manufacturing a patterned base member of the first embodiment. FIG. 2A to FIG. 2F schematically illustrate the method of manufacturing a patterned base member of the first embodiment.

As shown in FIG. 1, the method of manufacturing the patterned base member according to the first embodiment includes a step S101 of forming a resist layer, a step S102 of forming an exposed portion and an unexposed portion, a step S103 of providing a patterned resist layer, an electron beam irradiation step S104, and an etching step S105. The method of the present embodiment can reduce the degree of the change in shape of the patterned resist layer by etching and can improve the accuracy of the pattern of the resulting patterned base member.

### Step S101 of Forming Resist Layer

A resist layer 2 is first formed on a base member 1 as shown in FIG. 2A. The resist layer 2 is made of a positive resist. The resist layer 2 is a resist for exposure with an electron beam. For example, the resist layer 2 can be formed by application. For example, the resist layer 2 can have a thickness of 10 nm or more and 1,000 nm or less.

A positive resist is a resist that becomes more soluble in a developing solution through electron beam irradiation. For example, a chemically amplified positive resist can be used as the positive resist. For the positive resist, for example, poly(methyl methacrylate) (PMMA) (such as a product manufactured by MicroChem Corporation in the U.S.), polymethylglutarimide (PMGI) (such as a product manufactured by MicroChem Corporation in the U.S.), or ZEP520 manufactured by Zeon Corporation can be used.

The base member 1 is a material to be processed in the etching step S105, which is a subsequent step. Examples of the material of the base member 1 include semiconductors such as silicon and nitride semiconductors and glass.

### Step S102 of Forming Exposed Portion and Unexposed Portion

Subsequently, a portion of the resist layer 2 is exposed to an electron beam EB to form an exposed portion 2a and an unexposed portion 2b in the resist layer 2 as shown in FIG. 2B and FIG. 2C. The exposed portion 2a can be formed by drawing using the electron beam EB. Formation of the exposed portion 2a by electron beam drawing is suitable for forming a fine pattern. Electron beam drawing is a method of irradiating a certain place with an electron beam without a mask. Electron beam drawing may be performed by intermittent irradiation while moving the position irradiated with the electron beam. The spot size of the electron beam applied to the resist layer 2 per shot can be determined according to the size of the exposed portion 2a to be formed. For example, the electron beam can have the spot size of 10 nm or more and less than 100 nm.

The exposed portion 2a can have a regular pattern made of a plurality of regions as shown in FIG. 2B. The exposed portion 2a may include a plurality of stripe regions regularly arranged in a top view. A pitch P of the stripe regions can be less than 1 μm. By the method of the present embodiment, the accuracy of the resulting pattern can be improved even in the case where an exposed portion 2a having such a fine shape is formed. The pitch P may be 500 nm or less or may be 100 nm or less. For example, the pitch P may be 20 nm or more. The stripe regions of the exposed portion 2a each have one long side and another long side. The pitch P refers to the distance from one long side of a stripe region to one long side of an adjacent stripe region. The exposed portion 2a may have a shape such as circular, elliptic, and polygonal shapes, a combination of these shapes, or a netlike shape in a top view.

The area of the exposed portion 2a is preferably smaller than the area of the unexposed portion 2b in a top view. The time taken by electron beam drawing can thus be shorter than otherwise. The ratio of the area of the exposed portion 2a to the area of the unexposed portion 2b is preferably less than 1, more preferably ½ or less, still more preferably ⅙ or less. For example, the shape and arrangement of the exposed portion 2a may be determined so that the exposed portion 2a does not reach the outer edges of the resist layer 2 in a top view as shown in FIG. 2B. The resist layer 2 is a positive resist, and the region directly below the region provided with the exposed portion 2a is intended to be processed. In the case where similar processing is performed using a negative resist as the resist layer 2, the arrangements of the exposed portion and the unexposed portion are reversed, and the area of the exposed portion is larger than the area of the unexposed portion in the case where processing is to be performed to provide such a shape as shown in FIG. 2B. Using a positive resist as the resist layer 2 can shorten the time taken by electron beam drawing for exposure to light as compared with the case where a negative resist is used.

The depth of the exposed portion 2a may be equal to or smaller than the thickness of the resist layer 2. For example, the depth of the exposed portion 2a can be one half or more of the thickness of the resist layer 2. The depth of the exposed portion 2a may be adjusted by changing the intensity and the irradiation time of the electron beam applied.

### Step S103 of Providing Patterned Resist Layer

Subsequently, the resist layer 2 is developed as shown in FIG. 2D to remove the exposed portion 2a and leave the unexposed portion 2b, thereby providing a patterned resist layer 3. In FIG. 2D, the base member 1 is exposed in a portion in which the exposed portion 2a has been removed. The exposed portion 2a may be removed to the extent that the base member 1 is not exposed. In this case, the patterned resist layer 3 has a shape having recesses and projections.

The resist layer 2 can be developed by immersing a complex including the base member 1 and the resist layer 2 in a developing solution. Through immersion in the developing solution, the exposed portion 2a is dissolved in the developing solution, and the unexposed portion 2b remains. Examples of the developing solution used for the development include an alkaline aqueous solution in which at least one alkaline compound is dissolved. Examples of the alkaline compound include sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, and 1,5-diazabicyclo-[4.3.0]-5-nonene. The developing solution may be an organic solvent such as hydrocarbon solvents, ether solvents, ester solvents, ketone solvents, and alcohol solvents or a solvent containing an organic solvent.

Before the immersion in the developing solution, the resist layer 2 may be heated to make a difference in solubility in the developing solution between the exposed portion 2a and the unexposed portion 2b. For example, the temperature for the heating can be 50° C. to 180° C. For example, the time for the heating can be 5 seconds to 600 seconds. After the immersion in the developing solution, washing with a rinse liquid such as water and/or alcohol and drying may be performed.

### Electron Beam Irradiation Step S104

Subsequently, the patterned resist layer 3 is irradiated with the electron beam EB as shown in FIG. 2E. The degree of the change in shape of the patterned resist layer 3 can thus be reduced in the etching step S105, which is a subsequent step, and the accuracy of the resulting pattern can be improved.

The whole or a portion of the patterned resist layer 3 may be irradiated with the electron beam EB. The region irradiated with the electron beam EB preferably includes at least a boundary portion of the pattern of the patterned resist layer 3. The region irradiated with the electron beam EB preferably includes at least a whole patterned portion of the pattern of the patterned resist layer 3. The degree of the change in shape of the boundary portion of the pattern can thus be reduced in the etching step S105, which is a subsequent step, and the accuracy of the processing pattern formed in the base member 1 can be more certainly improved. For example, an entirety of patterned resist layer 3 is irradiated with the electron beam EB. For example, at least an entirety of a patterned portion of patterned resist layer 3 is irradiated with the electron beam EB.

The patterned resist layer 3 may be irradiated with the electron beam EB using a similar electron beam to the beam used in the step S102 of forming an exposed portion and an unexposed portion by electron beam drawing. In this case, the irradiation time can be shortened by irradiating only a portion of the patterned resist layer 3 with the electron beam EB. The beam size of the electron beam EB applied to the patterned resist layer 3 may be large enough to irradiate the whole patterned resist layer 3 at once. This constitution allows the whole patterned resist layer 3 to be irradiated with the electron beam EB in a shorter time than in the case of electron beam drawing. Examples of the method of irradiating the whole patterned resist layer 3 with the electron beam EB at once include a method disclosed in Japanese Translation of PCT International Application Publication No. JP-T-2003-502698.

### Etching Step S105

Subsequently, the base member 1 is etched using the patterned resist layer 3 as an etching mask. A patterned base member 4 can thus be provided as shown in FIG. 2F. The electron beam irradiation step S104 has been performed, and the degree of the change in shape of the patterned resist layer 3 through etching can be reduced. The accuracy of the pattern formed in the resulting patterned base member 4 can thus be improved. The etching step S105 may be performed by etching the base member 1 using a patterned mask layer to which the pattern of the patterned resist layer 3 has been transferred as an etching mask.

For example, the etching is dry etching. By dry-etching the base member 1, a pattern closer to the pattern of the etching mask can be formed in the base member 1 than in the case of wet etching. In the case of dry etching, the shape of the patterned resist layer 3 may change due to local growth of the patterned resist layer 3 caused by a reaction with an etching gas. By performing the electron beam irradiation step S104, such a reaction of the patterned resist layer 3 with the etching gas may be suppressed. A gas that has a lower etching rate for the patterned resist layer 3 than the etching rate for a workpiece such as the base member 1 is selected as the etching gas. For example, a gas containing at least one of a chlorine-based gas and a fluorine-based gas can be used as the etching gas.

The etching step S105 may be performed until the patterned resist layer 3 is completely removed or may be stopped to leave the patterned resist layer 3. In the case where the patterned resist layer 3 is left after the etching step S105, a step of removing the patterned resist layer 3 may be performed after the etching step S105.

### Modification

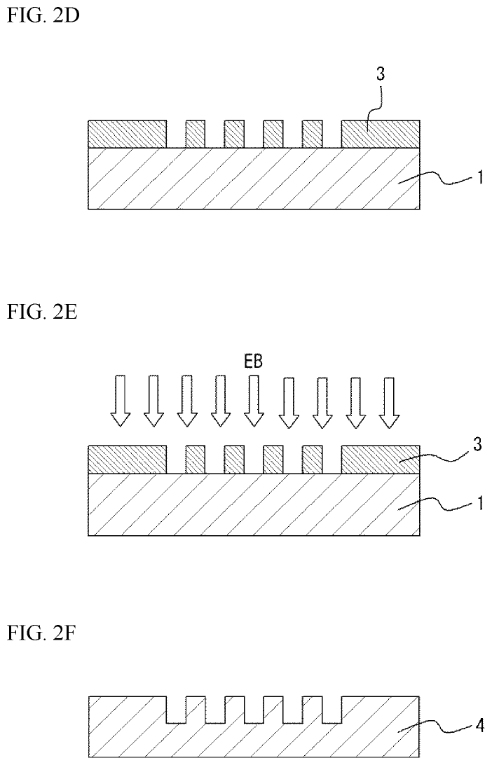

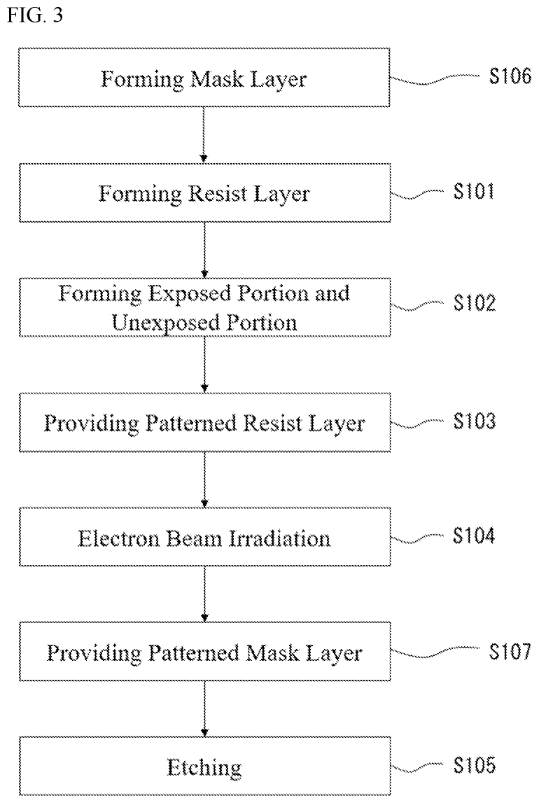

As a modification, the following describes an example in the case where the etching step S105 is performed using a patterned mask layer to which the pattern of the patterned resist layer 3 has been transferred as an etching mask. FIG. 3 is a flowchart illustrating a manufacturing method of the modification. FIG. 4A to FIG. 4C schematically illustrate the manufacturing method of the modification. The manufacturing method of the modification includes a step S106 of forming a mask layer before the step S101 of forming a resist layer and includes a step S107 of providing a patterned mask layer after the electron beam irradiation step S104.

### Step S106 of Forming Mask Layer

A mask layer 5 is formed on the base member 1 as shown in FIG. 4A. The resist layer 2 is formed on the mask layer 5. The material of the mask layer 5 is selected such that the etching rate for the mask layer 5 is larger than the etching rate for the patterned resist layer 3. For example, the mask layer 5 is a silicon oxide film. The silicon oxide film may be a SiO₂ film.

### Step S107 of Providing Patterned Mask Layer

After the patterned resist layer 3 is provided as shown in FIG. 4B, the mask layer 5 is etched using the patterned resist layer 3 as an etching mask to provide a patterned mask layer 6 as shown in FIG. 4C, and thus, the pattern of the patterned resist layer 3 is transferred to the patterned mask layer 6. The patterned resist layer 3 remains on the patterned mask layer 6 in the example shown in FIG. 4C, but the patterned resist layer 3 may be removed.

For example, the etching is dry etching. Dry-etching of the mask layer 5 allows a pattern closer to the pattern of the patterned resist layer 3 to be formed in the mask layer 5 than in the case of wet etching. By performing the electron beam irradiation step S104 earlier, the reaction of the patterned resist layer 3 with the etching gas may be suppressed. A gas that has a lower etching rate for the patterned resist layer 3 than the etching rate for the mask layer 5 is selected as the etching gas. For example, a gas containing at least one of a chlorine-based gas and a fluorine-based gas can be used as the etching gas.

The etching may be performed until the patterned resist layer 3 is completely removed or may be stopped to leave the patterned resist layer 3. In the case where the patterned resist layer 3 is left after the step S107 of providing a patterned mask layer, a step of removing the patterned resist layer 3 may be performed before the etching step S105, or the patterned resist layer 3 may remain.

The base member 1 is then etched using the patterned mask layer 6 as an etching mask in the etching step S105. In the case where the patterned resist layer 3 is left, the patterned resist layer 3 is also considered to be a portion of the etching mask. In the case where the etching rate for the patterned resist layer 3 is larger than the etching rate for the base member 1 in the etching step S105, the patterned mask layer 6 is preferably formed in this way. The base member 1 can thus be efficiently processed. The etching rate for the patterned mask layer 6 is preferably smaller than the etching rate for the base member 1 in the etching step S105. The base member 1 can thus be more efficiently processed. For example, the patterned mask layer 6 can be a silicon oxide film, and the base member 1 can be a nitride semiconductor substrate. The etching rate for the etching mask does not necessarily have to be smaller than the etching rate for the base member 1 in the etching step S105. In this case, the etching mask has such a thickness to prevent the etching mask from being completely removed during the etching step S105.

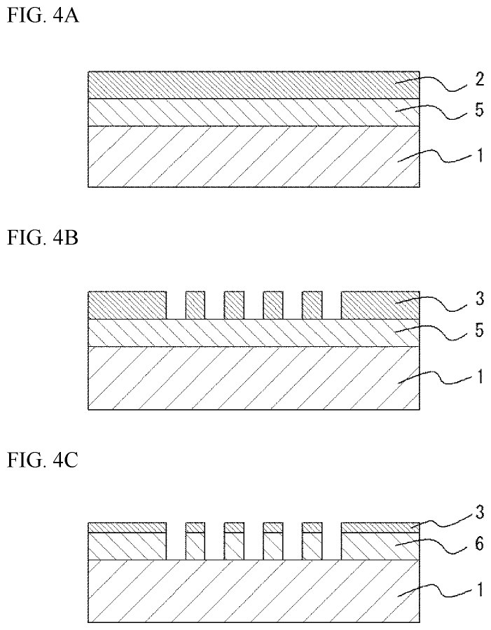

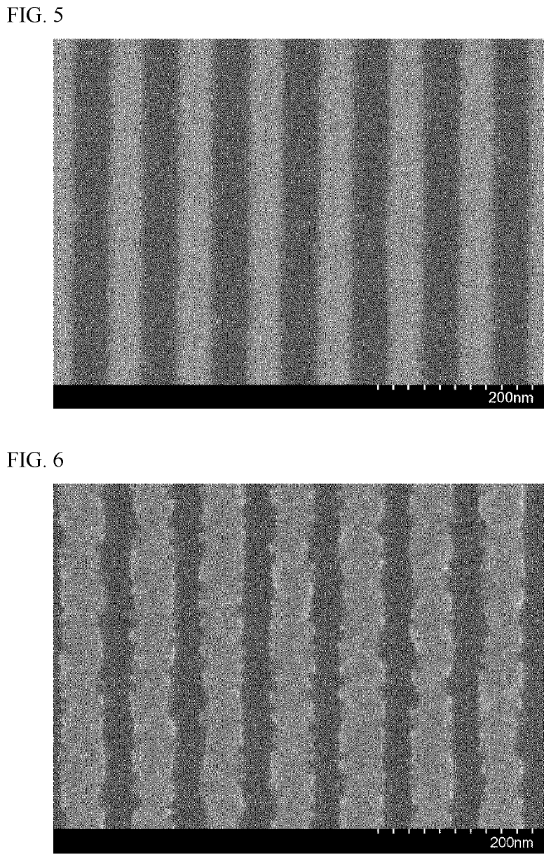

FIG. 5 shows a micrograph of the patterned resist layer 3 after the electron beam irradiation step S104 and dry etching as the step S107 of providing a patterned mask layer taken with a scanning electron microscope (SEM). In FIG. 5, the electron beam irradiation step S104 has been performed using an electron gun installed in the SEM. FIG. 6 shows a SEM micrograph of the patterned resist layer 3 after dry etching as the step S107 of providing a patterned mask layer without the electron beam irradiation step S104. The micrographs of FIG. 5 and FIG. 6 are both taken from the upper surfaces, and light gray portions are the patterned resist layer 3. The pitches are both about 95 nm. The reason why the shape of the patterned resist layer 3 changed as shown in FIG. 6 is considered to be that the patterned resist layer 3 that did not have undergone the electron beam irradiation step S104 reacted with the etching gas in the dry etching.

### Second Embodiment

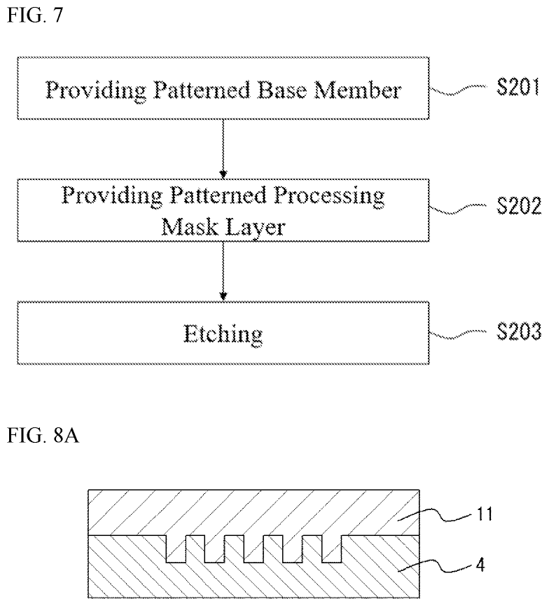

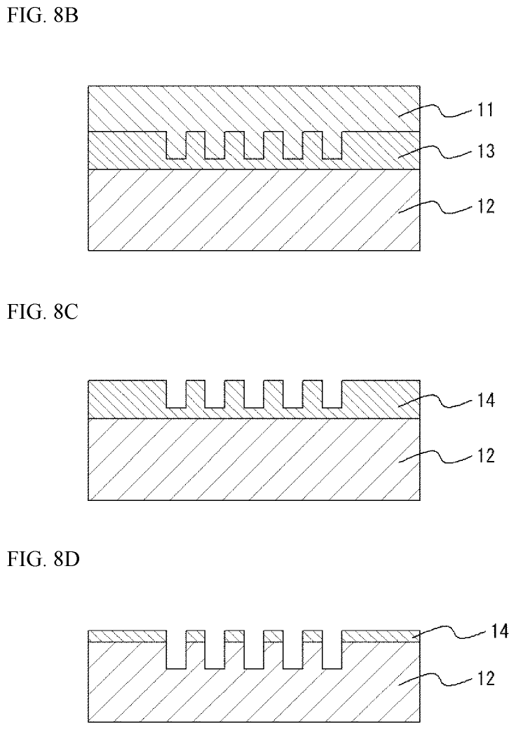

A processing method according to a second embodiment is described referring to FIG. 7 to FIG. 8E. FIG. 7 is a flowchart illustrating the processing method of the second embodiment. FIG. 8A to FIG. 8E schematically illustrate the processing method of the second embodiment.

As shown in FIG. 7, the processing method according to the second embodiment includes a step S201 of providing a patterned base member, a step S202 of providing a patterned processing mask layer, and an etching step S203. The method of the present embodiment can improve the processing accuracy.

### Step S201 of Providing Patterned Base Member

The patterned base member 4 is provided by the method described for the first embodiment.

### Step S202 of Providing Patterned Processing Mask Layer

Subsequently, the pattern of the patterned base member 4 is transferred to a processing resist layer 13 disposed on a workpiece 12 to provide a patterned processing mask layer 14. The pattern of the patterned base member 4 may be directly transferred to the processing resist layer or may be transferred using a replica mold 11 as an intermediate as shown in FIG. 8A to FIG. 8C. In the case of direct transfer to the processing resist layer 13, the inverse of the protrusions and depressions of the pattern of the patterned base member 4 constitutes the pattern of the patterned processing mask layer 14, but in the case of using the replica mold 11 as an intermediate, the protrusions and depressions of the pattern of the patterned base member 4 constitute the pattern of the patterned processing mask layer 14 as they are. The pattern transfer may refer to any of the above operations. The pattern of the patterned base member 4 can be transferred to the patterned processing mask layer 14 by a known imprinting technique.

In the case of using the replica mold 11 as an intermediate, a step of forming the replica mold 11 using the patterned base member 4 as a mold is further included. The pattern of the replica mold 11 is then transferred to the processing resist layer 13 disposed on the workpiece 12 in the step S202 of providing a patterned processing mask layer 14 to provide the patterned processing mask layer 14. In the case of using the replica mold 11 as an intermediate, the replica mold 11 may be repeatedly used to form the patterned processing mask layer 14, and a new replica mold 11 may be produced using the patterned base member 4 again when the pattern of the replica mold 11 is worn. Accordingly, the processing accuracy of the pattern can be further improved.

As the materials of the replica mold 11 and the processing resist layer 13, materials used in a known imprinting technique can be employed. For example, a cured product provided by pressing the patterned base member 4 against a UV-curable resist and curing the resist by UV irradiation can be used as the replica mold 11. For example, a cured product provided by pressing the replica mold 11 against a UV-curable processing resist layer 13 and curing the layer by UV irradiation can be used as the patterned processing mask layer 14. The replica mold 11 may be constituted of a complex member of a substrate and a resist.

### Etching Step S203

The workpiece 12 is etched using the patterned processing mask layer 14 as an etching mask as shown in FIG. 8D. A patterned workpiece 15 can thus be provided as shown in FIG. 8E. The same etching mask and etching method as in the etching step S105 described for the first embodiment can be employed. For example, the etching mask may be the patterned mask layer in the first modification described above.

### Third Embodiment

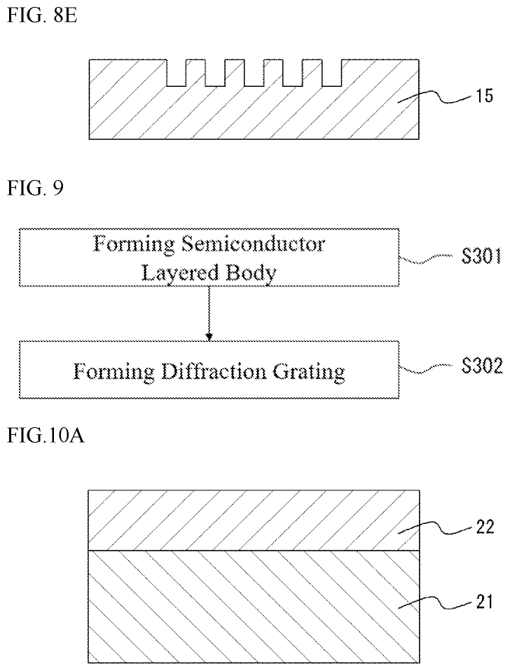

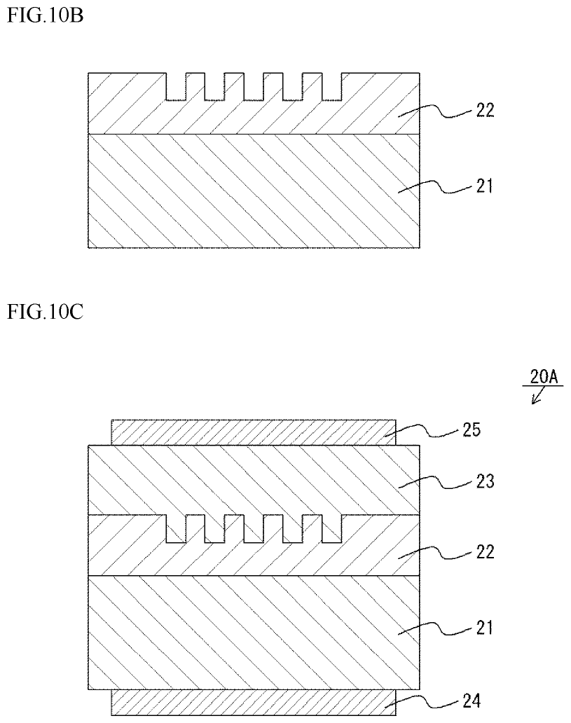

A method of manufacturing a laser element according to a third embodiment is described referring to FIG. 9 to FIG. 10C. FIG. 9 is a flowchart illustrating the method of manufacturing a laser element of the third embodiment. FIG. 10A to FIG. 10C schematically illustrate the method of manufacturing a laser element of the third embodiment.

As shown in FIG. 9, the method of manufacturing a laser element according to the third embodiment includes a step S301 of forming a semiconductor layered body and a step S302 of forming a diffraction grating. The method of the present embodiment can improve the accuracy of the pattern of the resulting laser element.

### Step S301 of Forming Semiconductor Layered Body

A first semiconductor layered body 22 in which a plurality of semiconductor layers are layered is formed as shown in FIG. 10A. The first semiconductor layered body 22 can be formed on a substrate 21. For example, the substrate 21 is a semiconductor substrate. Examples of the semiconductor substrate include substrates made of nitride semiconductors such as GaN, AlGaN, and AlN. For example, the substrate 21 is an electroconductive substrate. The substrate 21 may be an insulating substrate. Examples of the semiconductor constituting the first semiconductor layered body 22 include group III to V semiconductors. For example, the semiconductor constituting the first semiconductor layered body 22 is a nitride semiconductor such as GaN, AlGaN, AlN, AlInGaN, and InGaN. For example, the first semiconductor layered body 22 can be formed by metal organic chemical vapor deposition (MOCVD).

### Step S302 of Forming Diffraction Grating

Subsequently, a diffraction grating is formed in the first semiconductor layered body 22 as shown in FIG. 10B by the processing method described for the second embodiment. For example, the diffraction grating is formed at a position corresponding to a resonator of the resulting laser element. In this case, for example, exposure to light is performed such that the area of the exposed portion 2a is smaller than the area of the unexposed portion 2b as shown in FIG. 2B.

After the step S302 of forming a diffraction grating, a second semiconductor layered body 23 may be formed on the first semiconductor layered body 22 as shown in FIG. 10C. The second semiconductor layered body 23 can be formed to fill the diffraction grating formed in the first semiconductor layered body 22. For example, the second semiconductor layered body 23 can be formed by MOCVD. For example, in the case where the semiconductor constituting the first semiconductor layered body 22 is a nitride semiconductor, the semiconductor constituting the second semiconductor layered body 23 may also be a nitride semiconductor. A layered body made of the first semiconductor layered body 22 and the second semiconductor layered body 23 includes an n-type semiconductor layer, a p-type semiconductor layer, and an active layer between these layers. A first electrode 24 and a second electrode 25 are formed to provide a laser element 20A. The step S301 of forming a semiconductor layered body and the step S302 of forming a diffraction grating may be performed in the form of a wafer, and the resulting wafer may be singulated to provide a plurality of laser elements 20A. For example, the laser element 20A is a distributed feedback (DFB) laser element. The pattern of the diffraction grating formed in the step S302 of forming a diffraction grating becomes finer as the peak wavelength of the laser beam emitted from the laser element 20A is reduced. For example, the peak wavelength of the laser beam emitted from the laser element 20A can be 200 nm or more and 600 nm or less and may be 200 nm or more and 500 nm or less. For example, the laser element 20A that emits a laser beam with such a wavelength can be formed by constituting the layered body made of the first semiconductor layered body 22 and the second semiconductor layered body 23 using a nitride semiconductor.

### Fourth Embodiment

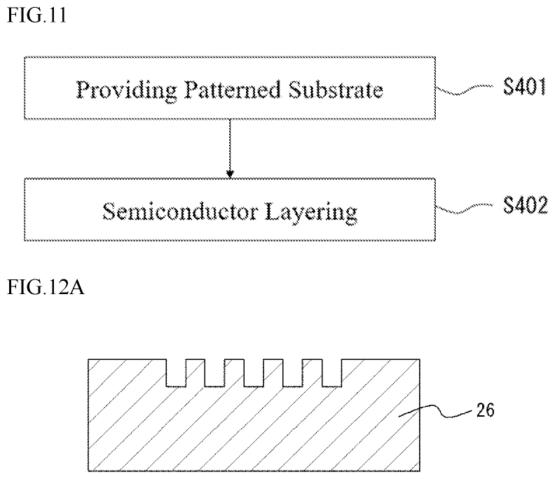

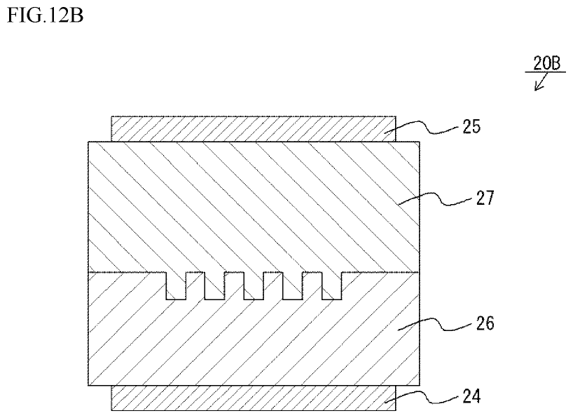

A method of manufacturing a laser element according to a fourth embodiment is described referring to FIG. 11 to FIG. 12B. FIG. 11 is a flowchart illustrating the method of manufacturing a laser element of the fourth embodiment. FIG. 12A and FIG. 12B schematically illustrate the method of manufacturing a laser element of the fourth embodiment.

As shown in FIG. 11, the method of manufacturing a laser element according to the fourth embodiment includes a step S401 of providing a patterned substrate and a semiconductor layering step S402. The method of the present embodiment can improve the accuracy of the pattern of the resulting laser element.

### Step S401 of Providing Patterned Substrate

As shown in FIG. 12A, a patterned substrate 26 is first provided as the patterned base member by the method described for the first embodiment. In this case, the base member 1 described for the first embodiment is preferably a nitride semiconductor substrate. A nitride semiconductor substrate is suitable for providing a nitride semiconductor laser element as a laser element 20B. Examples of the nitride semiconductor substrate include a GaN substrate, an InGaN substrate, an AlGaN substrate, and an AlN substrate. For example, the patterned substrate 26 is an electroconductive substrate. The patterned substrate 26 may be an insulating substrate.

### Semiconductor Layering Step S402

Subsequently, a plurality of semiconductor layers are layered on the patterned substrate 26 as shown in FIG. 12B. By layering a plurality of semiconductor layers, a semiconductor layered body 27 is formed. For example, the semiconductor layered body 27 can be formed by MOCVD. The semiconductor layered body 27 includes an n-type semiconductor layer, a p-type semiconductor layer, and an active layer between these layers. The first electrode 24 and the second electrode 25 are formed to provide the laser element 20B. The step S401 of providing a patterned substrate and the semiconductor layering step S402 may be performed in the form of a wafer, and the resulting wafer may be singulated to provide a plurality of laser elements 20B. For example, the laser element 20B is a DFB laser element. In this case, the pattern formed in the patterned substrate 26 is a diffraction grating.

Examples of the semiconductor constituting the semiconductor layered body 27 include group III to V semiconductors. For example, the semiconductor constituting the semiconductor layered body 27 is a nitride semiconductor such as GaN, AlGaN, AlN, AlInGaN, and InGaN. For example, the peak wavelength of the laser beam emitted from the laser element 20A can be 200 nm or more and 600 nm or less and may be 200 nm or more and 500 nm or less. For example, the laser element 20B that emits a laser beam with such a wavelength can be formed by constituting the semiconductor layered body 27 using a nitride semiconductor.

The patterned base member 4 provided in the first embodiment may be used as a portion of the laser element 20B as described above without using the processing method described for the second embodiment. The patterned base member 4 is a substrate in the fourth embodiment, but a portion of the semiconductor layered body may be the patterned base member 4. The patterned substrate 26 may be provided by the processing method described for the second embodiment.

1. A method of manufacturing a patterned base member, the method comprising:
forming a resist layer including a positive resist on a base member;
exposing a portion of the resist layer to an electron beam to form an exposed portion and an unexposed portion in the resist layer;
developing the resist layer to remove the exposed portion and leave the unexposed portion to provide a patterned resist layer;
irradiating an entirety of the patterned resist layer with an electron beam; and
etching the base member using the patterned resist layer as an etching mask or using a patterned mask layer, to which a pattern of the patterned resist layer is transferred, as an etching mask.

2. The method of manufacturing a patterned base member according to claim 1, wherein
in the irradiating of the entirety of the patterned resist layer, a beam size of the electron beam applied to the patterned resist layer is large enough to irradiate the entirety of the patterned resist layer at once.

3. The method of manufacturing a patterned base member according to claim 1, the method further comprising:
forming a mask layer on the base member before the forming of the resist layer; and
etching the mask layer using the patterned resist layer as an etching mask to form the patterned mask layer after the irradiating of the entirety of the patterned resist layer with the electron beam,
wherein the etching of the base member includes etching the base member using the patterned mask layer as the etching mask.

4. The method of manufacturing a patterned base member according to claim 1, wherein the etching is dry etching.

5. The method of manufacturing a patterned base member according to claim 1, wherein the exposing of the portion of the resist layer includes exposing the portion of the resist layer so that the exposed portion has a regular pattern including a plurality of regions.

6. The method of manufacturing a patterned base member according to claim 1, wherein
the exposing of the portion of the resist layer includes exposing the portion of the resist layer so that the exposed portion includes a plurality of stripe regions regularly arranged in a top view, and
a pitch of the plurality of stripe regions is less than 1 μm.

7. The method of manufacturing a patterned base member according to claim 1, wherein the exposing of the portion of the resist layer includes exposing the portion of the resist layer so that an area of the exposed portion is smaller than an area of the unexposed portion in a top view.

8. A processing method comprising:
providing the patterned base member manufactured by the method according to claim 1;
transferring a pattern of the patterned base member to a processing resist layer disposed on a workpiece to provide a patterned processing mask layer; and
etching the workpiece using the patterned processing mask layer as an etching mask.

9. A method of manufacturing a laser element, the method comprising:
forming a semiconductor layered body including a plurality of semiconductor layers; and
forming a diffraction grating in the semiconductor layered body by the processing method according to claim 8.

10. A method of manufacturing a laser element, the method comprising:
providing a patterned substrate as the patterned base member manufactured by the method according to claim 1 using a nitride semiconductor substrate as the base member; and
layering a plurality of semiconductor layers on the patterned substrate.

11. A method of manufacturing a patterned base member, the method comprising:
forming a resist layer including a positive resist on a base member;
exposing a portion of the resist layer to an electron beam to form an exposed portion and an unexposed portion in the resist layer;
developing the resist layer to remove the exposed portion and leave the unexposed portion to provide a patterned resist layer;
irradiating at least an entirety of a patterned portion of the patterned resist layer with an electron beam; and
etching the base member using the patterned resist layer as an etching mask or using a patterned mask layer to which a pattern of the patterned resist layer is transferred as an etching mask.

12. The method of manufacturing a patterned base member according to claim 11, the method further comprising:
forming a mask layer on the base member before the forming of the resist layer; and
etching the mask layer using the patterned resist layer as an etching mask to form the patterned mask layer after the irradiating of the at least the entirety of the patterned portion of the patterned resist layer with the electron beam,
wherein the etching of the base member includes etching the base member using the patterned mask layer as the etching mask.

13. The method of manufacturing a patterned base member according to claim 11, wherein the etching is dry etching.

14. The method of manufacturing a patterned base member according to claim 11, wherein the exposing of the portion of the resist layer includes exposing the portion of the resist layer so that the exposed portion has a regular pattern including a plurality of regions.

15. The method of manufacturing a patterned base member according to claim 11, wherein
the exposing of the portion of the resist layer includes exposing the portion of the resist layer so that the exposed portion includes a plurality of stripe regions regularly arranged in a top view, and
a pitch of the plurality of stripe regions is less than 1 μm.

16. The method of manufacturing a patterned base member according to claim 11, wherein the exposing of the portion of the resist layer includes exposing the portion of the resist layer so that an area of the exposed portion is smaller than an area of the unexposed portion in a top view.

17. A processing method comprising:
providing the patterned base member manufactured by the method according to claim 11;
transferring a pattern of the patterned base member to a processing resist layer disposed on a workpiece to provide a patterned processing mask layer; and
etching the workpiece using the patterned processing mask layer as an etching mask.

18. A method of manufacturing a laser element, the method comprising:
forming a semiconductor layered body including a plurality of semiconductor layers; and
forming a diffraction grating in the semiconductor layered body by the processing method according to claim 17.

19. A method of manufacturing a laser element, the method comprising:
providing a patterned substrate as the patterned base member manufactured by the method according to claim 11 using a nitride semiconductor substrate as the base member; and
layering a plurality of semiconductor layers on the patterned substrate.
